(19) United States
(12) Patent Application Publication
(10) Pub. No.: US 2025/0301859 A1
(43) Pub. Date: Sep. 25, 2025

(54) MOTHER SUBSTRATE FOR DISPLAY DEVICE AND DISPLAY DEVICE

(71) Applicant: Japan Display Inc., Tokyo (JP)

(72) Inventor: Sho YANAGISAWA, Tokyo (JP)

(73) Assignee: Japan Display Inc., Tokyo (JP)

(21) Appl. No.: 19/083,461

(22) Filed: Mar. 19, 2025

(30) Foreign Application Priority Data
Mar. 22, 2024 (JP) 2024-046017

(51) Int. Cl. H10K 59/122; H10K 59/80

(52) U.S. Cl. CPC H10K 59/122; H10K 59/871

(57) ABSTRACT

According to one embodiment, a mother substrate for a display device includes panel portions including display and surrounding areas, a margin area around the panel portions, a display element in the display area, a rib layer which is in the panel portions and the margin area and has a pixel aperture, a first partition which is in the display area and surrounds the pixel aperture, and a second partition in at least one of the surrounding area and the margin area. The first partition includes a lower portion above the rib layer and an upper portion having an end portion protruding from a side surface of the lower portion. The second partition includes at least part of the lower portion and does not include the upper portion.

### CROSS-REFERENCE TO RELATED APPLICATION

This application is based upon and claims the benefit of priority from Japanese Patent Application No. 2024-046017, filed Mar. 22, 2024, the entire contents of which are incorporated herein by reference.

### FIELD

Embodiments described herein relate generally to a mother substrate for a display device, and a display device.

### BACKGROUND

Recently, display devices to which an organic light emitting diode (OLED) is applied as a display element have been put into practical use. In this type of display devices, a technique for improving the yield is required.

### BRIEF DESCRIPTION OF THE DRAWINGS

FIG. 1 is a diagram showing a configuration example of a display device according to a first embodiment.

FIG. 2 is a schematic plan view showing an example of the layout of subpixels.

FIG. 3 is the schematic cross-sectional view of a display panel along the III-III line of FIG. 2.

FIG. 4 is a schematic plan view of a mother substrate according to the first embodiment.

FIG. 5 is a schematic plan view of part of the mother substrate according to the first embodiment.

FIG. 6 is a schematic plan view showing an example of a second partition provided in a surrounding area and a margin area according to the first embodiment.

FIG. 7 is the schematic cross-sectional view of the mother substrate along the VII-VII line of FIG. 6.

FIG. 8 is a flowchart showing an example of the manufacturing method of the display device.

FIG. 9A is a schematic cross-sectional view showing the manufacturing process of the display device.

FIG. 9B is a schematic cross-sectional view showing a process following FIG. 9A.

FIG. 9C is a schematic cross-sectional view showing a process following FIG. 9B.

FIG. 9D is a schematic cross-sectional view showing a process following FIG. 9C.

FIG. 9E is a schematic cross-sectional view showing a process following FIG. 9D.

FIG. 9F is a schematic cross-sectional view showing a process following FIG. 9E.

FIG. 9G is a schematic cross-sectional view showing a process following FIG. 9F.

FIG. 9H is a schematic cross-sectional view showing a process following FIG. 9G.

FIG. 9I is a schematic cross-sectional view showing a process following FIG. 9H.

FIG. 9J is a schematic cross-sectional view showing a process following FIG. 9I.

FIG. 10A is a schematic cross-sectional view showing the second partitions and the surrounding structure in the manufacturing process of the display device.

FIG. 10B is another schematic cross-sectional view showing the second partitions and the surrounding structure in the manufacturing process of the display device.

FIG. 10C is yet another schematic cross-sectional view showing the second partitions and the surrounding structure in the manufacturing process of the display device.

FIG. 11A is a schematic cross-sectional view for explaining the process of providing an aperture in the rib layer and sealing layer of a terminal portion.

FIG. 11B is a schematic cross-sectional view showing a process following FIG. 11A.

FIG. 11C is a schematic cross-sectional view showing a process following FIG. 11B.

FIG. 11D is a schematic cross-sectional view showing a process following FIG. 11C.

FIG. 12 is a schematic cross-sectional view of partitions according to a comparative example.

FIG. 13 is a schematic cross-sectional view of the partitions for explaining the effect of the first embodiment.

FIG. 14 is a schematic cross-sectional view of a mother substrate according to a second embodiment.

FIG. 15 is a schematic plan view showing the surrounding area or margin area of a mother substrate according to a third embodiment.

FIG. 16 is the schematic cross-sectional view of the mother substrate along the XVI-XVI line of FIG. 15.

FIG. 17 is a schematic cross-sectional view of a display panel according to a fourth embodiment.

FIG. 18 is a flowchart showing an example of the manufacturing method of a display device according to the fourth embodiment.

FIG. 19 is a schematic plan view of a mother substrate according to a fifth embodiment.

### DETAILED DESCRIPTION

In general, according to one embodiment, a mother substrate for a display device comprises a plurality of panel portions each of which includes a display area and a surrounding area around the display area, a margin area around the panel portions, a display element in the display area, a rib layer which is in the panel portions and the margin area and has a pixel aperture overlapping the display element, a first partition which is in the display area and surrounds the pixel aperture, and a second partition which is in at least one of the surrounding area and the margin area. Further, the first partition includes a lower portion above the rib layer and an upper portion which has an end portion protruding from a side surface of the lower portion. The second partition includes at least part of the lower portion and does not include the upper portion.

According to another embodiment, a mother substrate for a display device comprises a plurality of panel portions each of which includes a display area and a surrounding area around the display area, a margin area around the panel portions, a display element in the display area, a rib layer which is in the panel portions and the margin area and has a pixel aperture overlapping the display element, and a first partition which is in the display area and has a partition aperture overlapping the pixel aperture. Further, in at least one of the surrounding area and the margin area, the rib layer has a recess which has a planar shape similar to the partition aperture, and a protrusion which surrounds the recess.

In general, according to one embodiment, a display device comprises a display area, a surrounding area around the display area, a display element in the display area, a rib layer which has a pixel aperture overlapping the display element, a first partition which is in the display area and surrounds the pixel aperture, and a second partition in the surrounding area. Further, the first partition includes a lower portion provided above the rib layer and an upper portion which has an end portion protruding from a side surface of the lower portion. The second partition includes at least part of the lower portion and does not include the upper portion.

According to another embodiment, a display device comprises a display area, a surrounding area around the display area, a display element in the display area, a rib layer having a pixel aperture overlapping the display element, and a first partition which is in the display area and has a partition aperture overlapping the pixel aperture. Further, in the surrounding area, the rib layer has a recess having a planar shape similar to the partition aperture, and a protrusion surrounding the recess.

In general, according to one embodiment, a manufacturing method of a display device includes preparing a substrate including panel portions each of which includes a display area and a surrounding area around the display area, and a margin area around the panel portions, forming a rib layer in the panel portions and the margin area, forming, in the display area, a first partition including a lower portion and an upper portion having an end portion protruding from a side surface of the lower portion, forming, in at least one of the margin area and the surrounding area, a second partition including the lower portion and the upper portion, forming a display element in an area surrounded by the first partition in the display area, and removing at least the upper portion from the second partition.

The embodiments can provide a mother substrate for a display device, a display device and a manufacturing method of a display device such that the yield can be improved.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

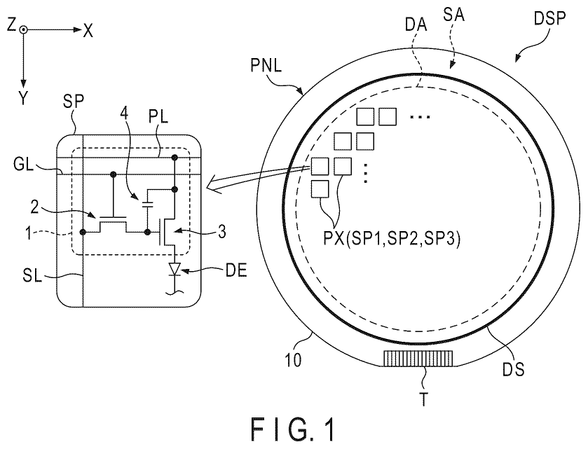

FIG. 1 is a diagram showing a configuration example of a display device DSP according to a first embodiment. The display device DSP comprises a display panel PNL including an insulating substrate 10. The display panel PNL has a display area DA which displays an image, and a surrounding area SA located around the display area DA. The substrate 10 may be glass or a resinous film having flexibility.

In the embodiment, the substrate 10 and the display area DA are circular as seen in plan view. It should be noted that the shape of each of the substrate 10 and the display area DA in plan view is not limited to a circle and may be another shape such as a rectangle, a square or an oval.

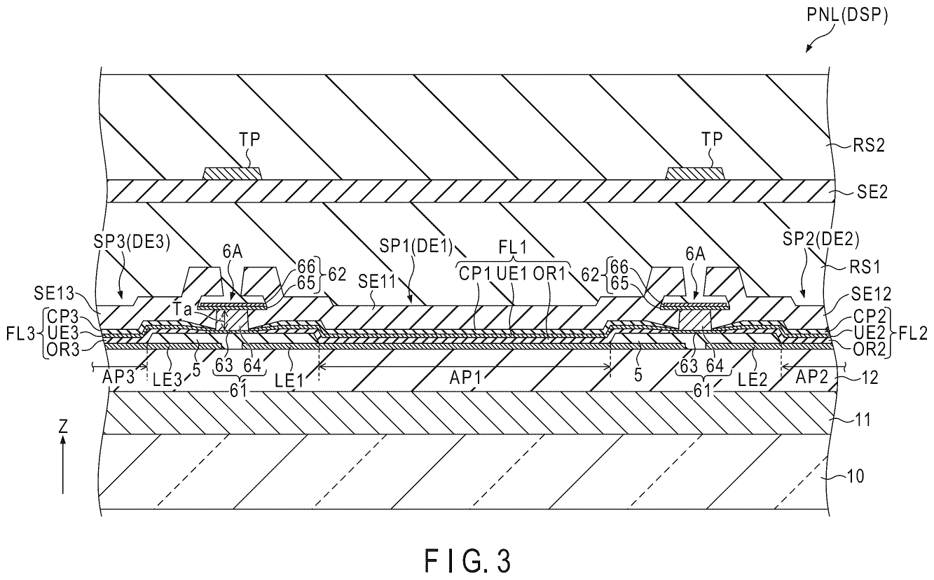

In the example of FIG. 1, an annular dam structure DS is provided in the surrounding area SA. The dam structure DS surrounds the display area DA. The shape of the dam structure DS in plan view is, for example, a circle. However, the shape is not limited to this example. The dam structure DS may be formed by, for example, an organic insulating layer 12 (see FIG. 3) as described later.

The display area DA comprises a plurality of pixels PX arrayed in matrix in an X-direction and a Y-direction. Each pixel PX includes a plurality of subpixels SP which display different colors. This embodiment assumes a case where each pixel PX includes subpixel SP1 which exhibits a first color, subpixel SP2 which exhibits a second color and subpixel SP3 which exhibits a third color. For example, the first color is blue, and the second color is green, and the third color is red. However, the colors are not limited to this example. Each pixel PX may include a subpixel SP which exhibits another color such as white in addition to subpixels SP1, SP2 and SP3 or instead of one of subpixels SP1, SP2 and SP3.

The display device DSP further comprises a terminal portion T provided in the surrounding area SA. For example, a flexible printed circuit which applies voltage and signals for driving the display device DSP is connected to the terminal portion T.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

A plurality of scanning lines GL which supply a scanning signal to the pixel circuit 1 of each subpixel SP, a plurality of signal lines SL which supply a video signal to the pixel circuit 1 of each subpixel SP and a plurality of power lines PL are provided in the display area DA. In the example of FIG. 1, the scanning lines GL and the power lines PL extend in the X-direction, and the signal lines SL extend in the Y-direction.

The gate electrode of the pixel switch 2 is connected to the scanning line GL. One of the source electrode and drain electrode of the pixel switch 2 is connected to the signal line SL. The other one is connected to the gate electrode of the drive transistor 3 and the capacitor 4. In the drive transistor 3, one of the source electrode and the drain electrode is connected to the power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

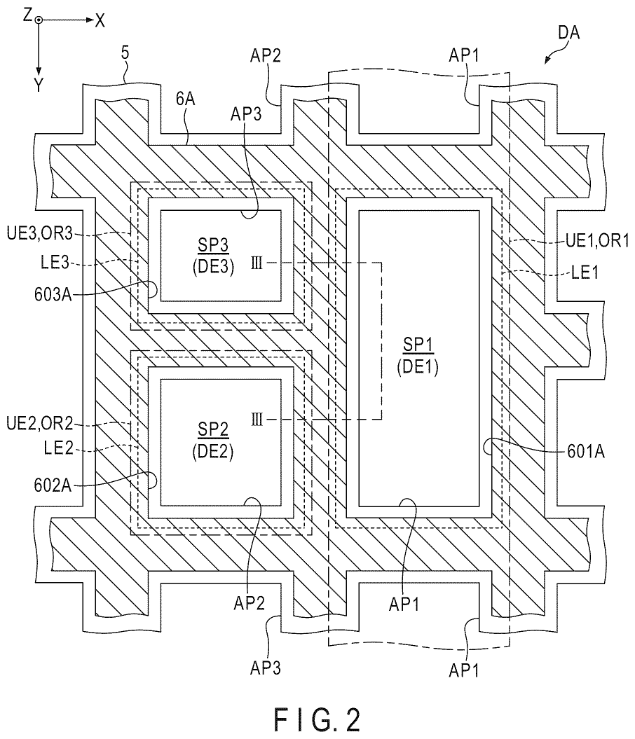

FIG. 2 is a schematic plan view showing an example of the layout of subpixels SP1, SP2 and SP3. In the example of FIG. 2, each of subpixels SP2 and SP3 is adjacent to subpixel SP1 in the X-direction. Further, subpixels SP2 and SP3 are arranged in the Y-direction.

When subpixels SP1, SP2 and SP3 are provided in line with this layout, a column in which subpixels SP2 and SP3 are alternately provided in the Y-direction and a column in which a plurality of subpixels SP1 are repeatedly provided in the Y-direction are formed in the display area DA. These columns are alternately arranged in the X-direction. It should be noted that the layout of subpixels SP1, SP2 and SP3 is not limited to the example of FIG. 2.

A rib layer 5 is provided in the display area DA. The rib layer 5 has pixel apertures (first to third pixel apertures) AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3. Thus, among subpixels SP1, SP2 and SP3, the aperture ratio of subpixel SP1 is the greatest, and the aperture ratio of subpixel SP3 is the least. It should be noted that the size of the pixel aperture AP1, AP2 or AP3 is not limited to this example.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element (first display element) DE1 of subpixel SP1. Of the lower electrode LE2, the upper electrode UE2 and the organic layer OR2, the portions which overlap the pixel aperture AP2 constitute the display element (second display element) DE2 of subpixel SP2. Of the lower electrode LE3, the upper electrode UE3 and the organic layer OR3, the portions which overlap the pixel aperture AP3 constitute the display element (third display element) DE3 of subpixel SP3. Each of the display elements DE1, DE2 and DE3 may further include a cap layer as described later. The rib layer 5 surrounds each of these display elements DE1, DE2 and DE3.

A conductive partition (first partition) 6A is provided above the rib layer 5. The partition 6A functions as lines which apply common voltage to the upper electrodes UE1, UE2 and UE3. The partition 6A overlaps the rib layer 5 as a whole and has a planar shape similar to that of the rib layer 5.

Specifically, the partition 6A has a partition aperture (first partition aperture) 601A in subpixel SP1, has a partition aperture (second partition aperture) 602A in subpixel SP2 and has a partition aperture (third partition aperture) 603A in subpixel SP3. The partition apertures 601A, 602A and 603A overlap the pixel apertures AP1, AP2 and AP3, respectively, as a whole. The partition apertures 601A, 602A and 603A overlap the display elements DE1, DE2 and DE3, respectively, as a whole. In other words, the partition 6A surrounds the display elements DE1, DE2 and DE3.

FIG. 3 is the schematic cross-sectional view of the display panel PNL along the III-III line of FIG. 2. A circuit layer 11 is provided on the substrate 10 described above. The circuit layer 11 includes various circuits and lines such as the pixel circuits 1, scanning lines GL, signal lines SL and power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib layer 5 is provided on the organic insulating layer 12 and the lower electrodes LE1, LE2 and LE3. The end portions of the lower electrodes LE1, LE2 and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6A includes a conductive lower portion 61 provided on the rib layer 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6A is called an overhang shape.

In the example of FIG. 3, the lower portion 61 has a bottom layer 63 provided on the rib layer 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64.

In the example of FIG. 3, the upper portion 62 comprises a first top layer 65, and a second top layer 66 provided on the first top layer 65. For example, the width of the second top layer 66 is slightly less than that of the first top layer 65. It should be noted that the configuration is not limited to this example. The first top layer 65 and the second top layer 66 may have the same width.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the side surfaces of the lower portions 61 of the partition 6A.

The display element DE1 includes a cap layer CP1 provided on the upper electrode UE1. The display element DE2 includes a cap layer CP2 provided on the upper electrode UE2. The display element DE3 includes a cap layer CP3 provided on the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

Sealing layers (first sealing layers) SE11, SE12 and SE13 are provided in subpixels SP1, SP2 and SP3, respectively. The sealing layer SE11 continuously covers the stacked film FL1 and the partition 6A around subpixel SP1. The sealing layer SE12 continuously covers the stacked film FL2 and the partition 6A around subpixel SP2. The sealing layer SE13 continuously covers the stacked film FL3 and the partition 6A around subpixel SP3.

In the example of FIG. 3, the sealing layer SE11 located on the partition 6A between subpixels SP1 and SP2 is spaced apart from the sealing layer SE12 located on this partition 6A. The sealing layer SE11 located on the partition 6A between subpixels SP1 and SP3 is spaced apart from the sealing layer SE13 located on this partition 6A. It should be noted that two of the sealing layers SE11, SE12 and SE13 may be in contact with each other above the partition 6A.

For example, a gap is formed between each of the sealing layers SE11, SE12 and SE13 and the upper portion 62 of the partition 6A. The stacked films FL1, FL2 and FL3 may be provided in at least part of these gaps.

The sealing layers SE11, SE12 and SE13 are covered with a resin layer (first resin layer) RS1. The resin layer RS1 is covered with a sealing layer (second sealing layer) SE2. The sealing layer SE2 is covered with a resin layer (second resin layer) RS2. The resin layers RS1 and RS2 and the sealing layer SE2 are continuously provided in at least the entire display area DA and partly extend in the surrounding area SA as well.

In the example of FIG. 3, touch panel electrodes TP are provided on the sealing layer SE2. The touch panel electrodes TP are covered with the resin layer RS2. The touch panel electrodes TP may be formed by metal lines. These lines may face the partition 6A in a Z-direction. Further, the lines may have a planar shape similar to that of the partition 6A.

A cover member such as a polarizer, a protective film or a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as polyimide. Each of the rib layer 5 and the sealing layers SE11, SE12, SE13 and SE2 is formed of an inorganic insulating material such as silicon nitride (SiNx), silicon oxide (SiOx) or silicon oxynitride (SiON). For example, the rib layer 5 is formed of silicon oxynitride, and each of the sealing layers SE11, SE12, SE13 and SE2 is formed of silicon nitride. Each of the resin layers RS1 and RS2 is formed of, for example, a resinous material (organic insulating material) such as epoxy resin or acrylic resin.

Each of the lower electrodes LE1, LE2 and LE3 has a reflective layer formed of, for example, silver, and a pair of conductive oxide layers covering the upper and lower surfaces of the reflective layer. Each of the conductive oxide layers can be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

Each of the organic layers OR1, OR2 and OR3 consists of a plurality of thin films including a light emitting layer. For example, each of the organic layers OR1, OR2 and OR3 has a structure in which a hole injection layer, a hole transport layer, an electron blocking layer, a light emitting layer, a hole blocking layer, an electron transport layer and an electron injection layer are stacked in order in the Z-direction. It should be noted that each of the organic layers OR1, OR2 and OR3 may have another structure such as a tandem structure including a plurality of light emitting layers.

Each of the cap layers CP1, CP2 and CP3 has, for example, a multilayer structure in which a plurality of transparent layers are stacked. These transparent layers may include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE11, SE12 and SE13. It should be noted that at least one of the cap layers CP1, CP2 and CP3 may be omitted.

Each of the bottom layer 63 and stem layer 64 of the partition 6A is formed of a metal material. For the metal material of the bottom layer 63, for example, molybdenum, titanium, titanium nitride (TiN), a molybdenum-tungsten alloy (MoW) or a molybdenum-niobium alloy (MoNb) may be used. For the metal material of the stem layer 64, for example, aluminum, an aluminum-neodymium alloy (AlNd), an aluminum-yttrium alloy (AlY) or an aluminum-silicon alloy (AlSi) may be used. It should be noted that the stem layer 64 may be formed of an insulating material.

The first top layer 65 of the partition 6A is formed of, for example, a metal material. The second top layer 66 of the partition 6A is formed of, for example, a conductive oxide. For the metal material forming the first top layer 65, for example, titanium, titanium nitride, molybdenum, tungsten, a molybdenum-tungsten alloy or a molybdenum-niobium alloy can be used. For the conductive oxide forming the second top layer 66, for example, ITO or IZO can be used. It should be noted that the upper portion 62 may comprise three or more layers or may consist of a single layer. The upper portion 62 may further include a layer formed of an insulating material.

Common voltage is applied to the partition 6A. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively, based on the video signals of the signal lines SL.

The organic layers OR1, OR2 and OR3 emit light based on the application of voltage. Specifically, when a potential difference is formed between the lower electrode LE1 and the upper electrode UE1, the light emitting layer of the organic layer OR1 emits light in the wavelength range of the first color. When a potential difference is formed between the lower electrode LE2 and the upper electrode UE2, the light emitting layer of the organic layer OR2 emits light in the wavelength range of the second color. When a potential difference is formed between the lower electrode LE3 and the upper electrode UE3, the light emitting layer of the organic layer OR3 emits light in the wavelength range of the third color.

When the display device DSP is manufactured, a large mother substrate in which a plurality of areas (panel portions) each corresponding to the display panel PNL are formed is prepared. A configuration which may be applied to this mother substrate is explained below.

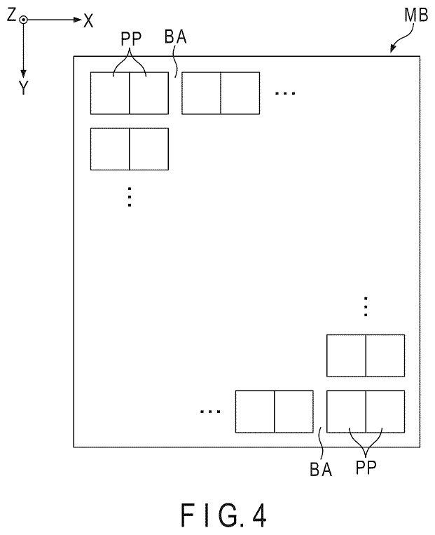

FIG. 4 is a schematic plan view of a mother substrate MB (a mother substrate for a display device) according to the embodiment. The mother substrate MB is, for example, rectangular as shown in the figure. However, the mother substrate MB may have another shape such as a circle.

The mother substrate MB comprises a plurality of panel portions PP provided in matrix, and a margin area BA located around these panel portions PP. In the example of FIG. 4, pairs of panel portions PP are arranged via the margin area BA in the X-direction and the Y-direction. It should be noted that the layout form of the panel portions PP in the mother substrate MB is not limited to this example.

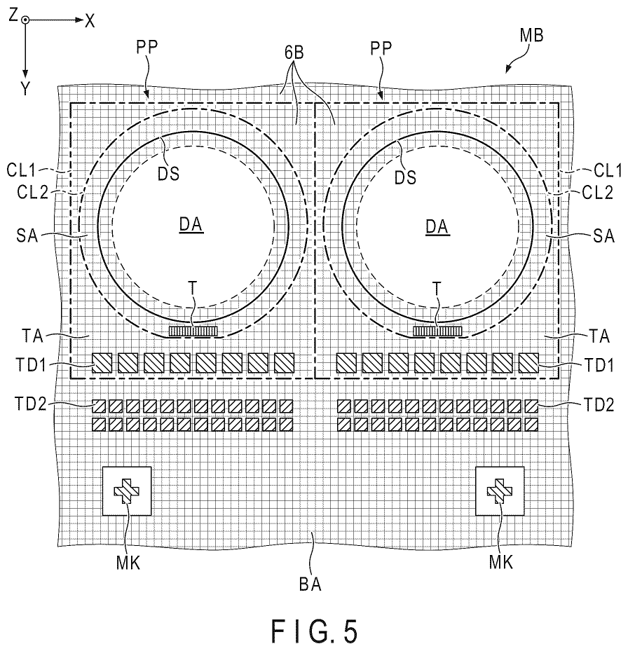

FIG. 5 is a schematic plan view of part of the mother substrate MB. This figure focuses attention on a pair of panel portions PP. The outer shape of each panel portion PP corresponds to a cut line CL1 for cutting the panel portion PP out of the mother substrate MB.

Each panel portion PP has the display area DA and surrounding area SA described above. Further, the surrounding area SA includes an inspection area TA. In the inspection area TA, a plurality of inspection pads TD1 for inspecting the operation of the display panel PNL are provided.

In each panel portion PP, a cut line CL2 is formed. The cut line CL2 corresponds to the outer shape of the display panel PNL shown in FIG. 1. By the cut line CL2, the panel portion PP is divided into a portion which includes the display area DA and a portion which includes the inspection area TA.

In the example of FIG. 5, a plurality of inspection pads TD2 are provided in the margin area BA as well. These inspection pads TD2 may include an inspection pad for inspecting the operation of the display panel PNL, and an inspection pad for measuring the thickness of a specific layer formed in the mother substrate MB. Further, a plurality of alignment marks MK are provided in the margin area BA.

When the display device DSP is manufactured, an inspection is performed using the inspection pads TD2, and subsequently, the panel portion PP is cut out from the mother substrate MB along the cut line CL1. Further, an inspection is performed for the cut out panel portion PP, using the inspection pads TD1. After this inspection, the inspection area TA is separated from the panel portion PP along the cut line CL2.

In this embodiment, a partition (second partition) 6B is provided in the margin area BA and the surrounding area SA. In FIG. 5, a grating pattern is added to the area in which the partition 6B could be provided. It should be noted that this grating pattern does not show the actual shape of the partition 6B.

The partition 6B may be provided in the area located between the display area DA and the dam structure DS, the area located between the dam structure DS and the cut line CL2, the area (inspection area TA) located between the cut lines CL1 and CL2, the margin area BA, etc. It should be noted that the partition 6B may not be provided in at least one of these areas. Further, the layout position and planar shape of the partition 6B in these areas may be appropriately determined.

To effectively cut out the panel portions PP, it is preferable that the partition 6B should not be provided in the cut lines CL1. Similarly, it is preferable that the partition 6B should not be provided in the cut lines CL2.

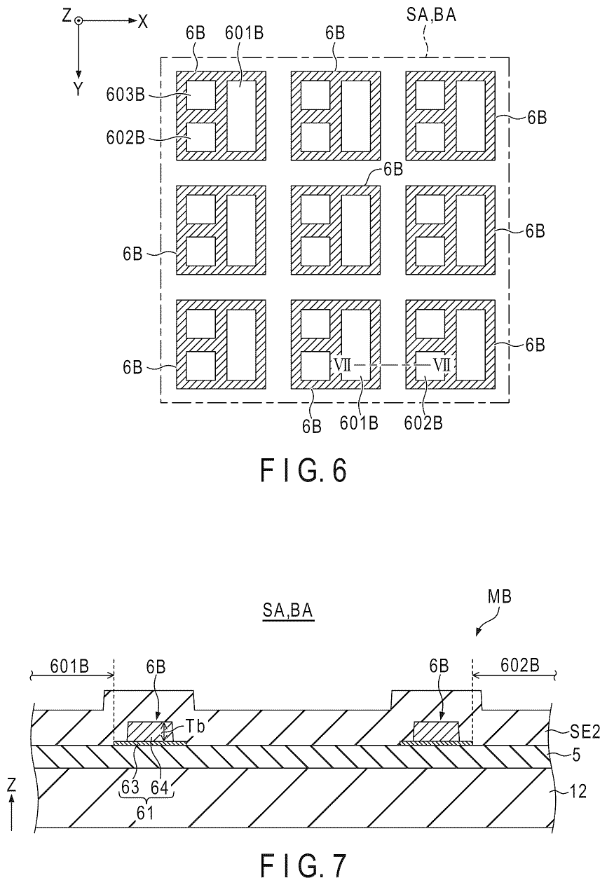

FIG. 6 is a schematic plan view showing an example of the partition 6B provided in the surrounding area SA and the margin area BA. In the example of this figure, a plurality of partitions 6B which are spaced apart from each other and each of which has a rectangular outer shape are provided. These partitions 6B are arranged in the X-direction and the Y-direction.

Each partition 6B has three partition apertures 601B, 602B and 603B. The planar shapes of the partition apertures 601B, 602B and 603B are similar to those of the partition apertures 601A, 602A and 603A shown in FIG. 2. Further, the relative positional relationship of the partition apertures 601B, 602B and 603B is similar to that of the partition apertures 601A, 602A and 603A.

Thus, in the example of FIG. 6, each of the partition apertures 602B and 603B is adjacent to the partition aperture 601B in the X-direction. Further, the partition apertures 602B and 603B are arranged in the Y-direction. The partition apertures 602B and 603B are smaller than the partition aperture 601B.

It should be noted that the shape of the partition aperture 601B, 602B or 603B or the relative positional relationship is not limited to the example of FIG. 6. Moreover, the partitions 6B having the shapes shown in FIG. 6 may not be necessarily provided in the entire part of the margin area BA and the surrounding area SA. In at least part of the margin area BA and the surrounding area SA, a partition 6B having another shape may be provided.

FIG. 7 is the schematic cross-sectional view of the mother substrate MB along the VII-VII line of FIG. 6. The rib layer 5, organic insulating layer 12 and sealing layer SE2 described above are formed in the surrounding area SA and the margin area BA as well. In FIG. 7, the elements of the lower side of the organic insulating layer 12 are omitted.

Each partition 6B is provided on the rib layer 5 and is covered with the sealing layer SE2. In this embodiment, each partition 6B includes a lower portion 61 in a manner similar to that of the partition 6A. However, each partition 6B does not include the upper portion 62.

The lower portion 61 of each partition 6B includes a bottom layer 63 and a stem layer 64 in a manner similar to that of the partition 6A. The bottom layer 63 and stem layer 64 of each partition 6B are formed of the same materials as the bottom layer 63 and stem layer 64 of the partition 6A, respectively. Thickness Tb of the stem layer 64 of each partition 6B should be preferably less than thickness Ta of the stem layer 64 of the partition 6A (see FIG. 3) (Tb<Ta). For example, the bottom layer 63 and stem layer 64 of each partition 6B are directly in contact with the sealing layer SE2.

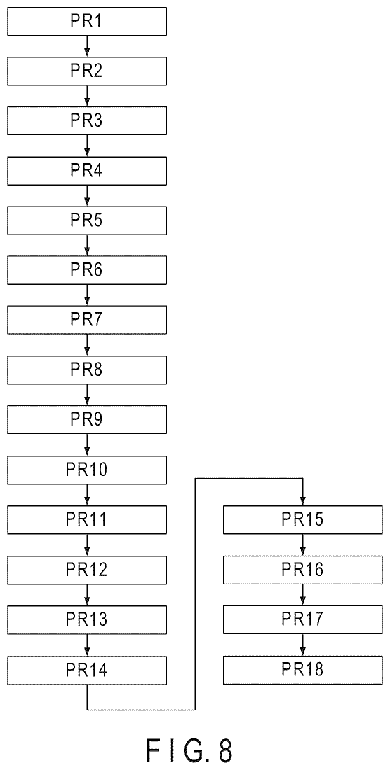

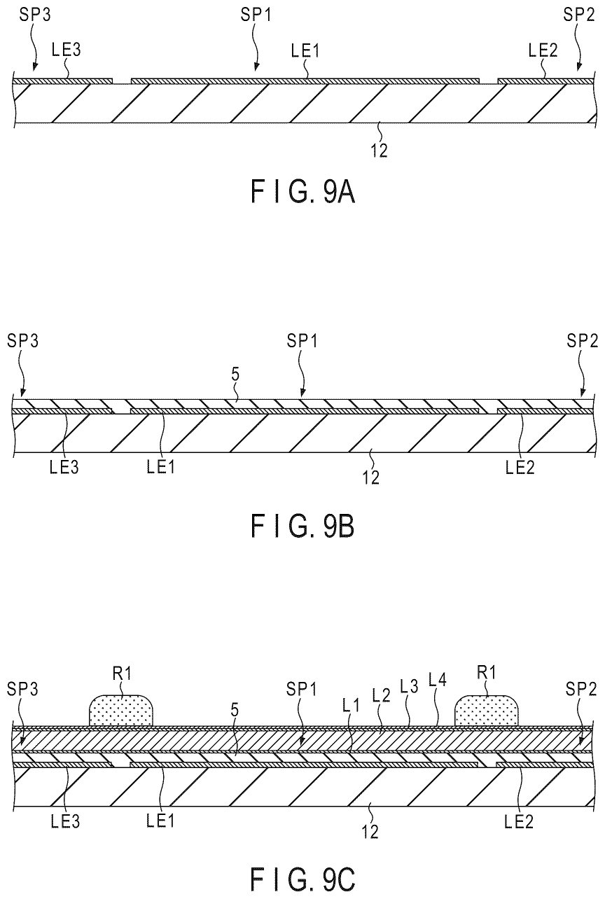

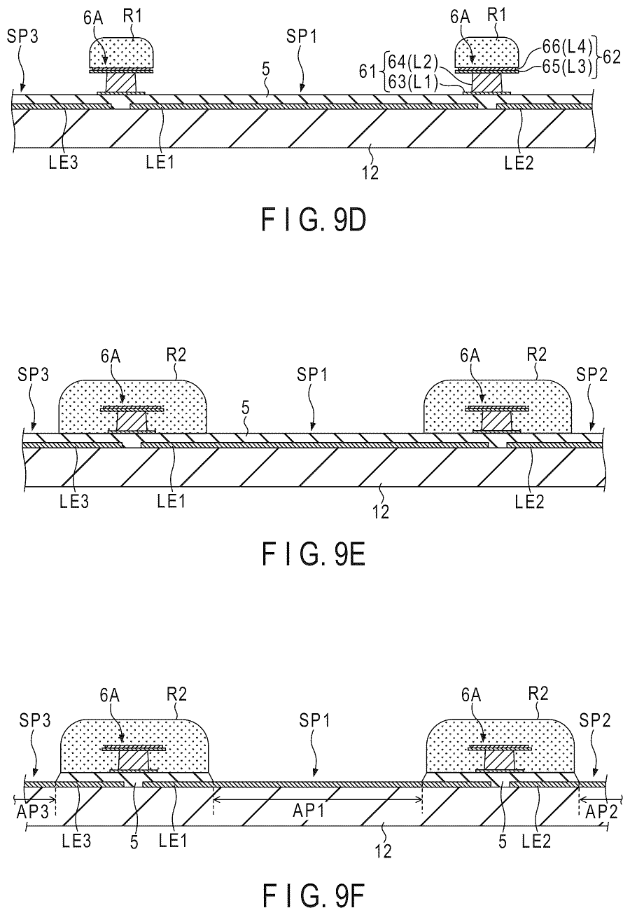

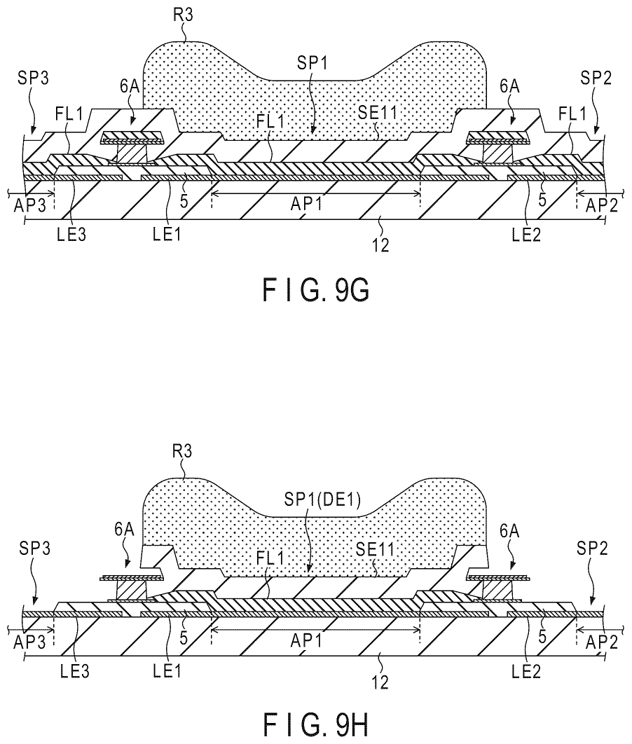

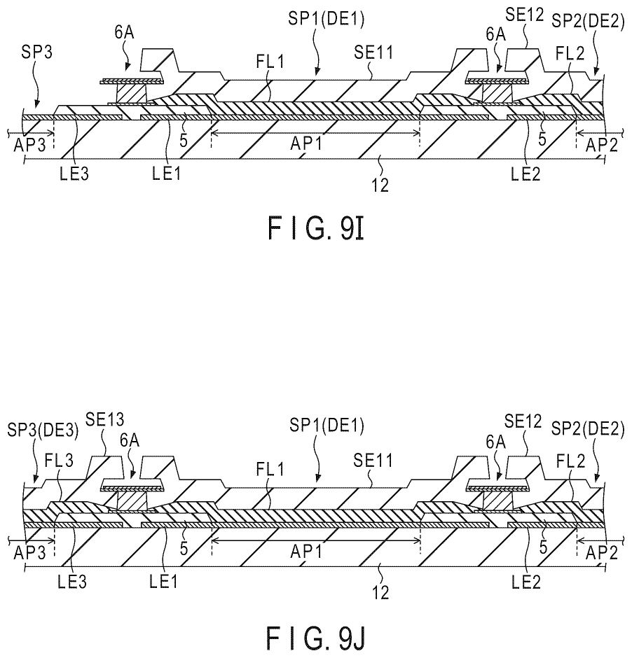

Now, this specification explains an example of the manufacturing method of the display device DSP. FIG. 8 is a flowchart showing an example of the manufacturing method of the display device DSP. Each of FIG. 9A to FIG. 9J is a schematic cross-sectional view showing the manufacturing process of the display device DSP. In FIG. 9A to FIG. 9J, the display area DA is mainly looked at, and the elements located on the lower side of the organic insulating layer 12 are omitted.

To form the panel portions PP, first, the circuit layer 11 and the organic insulating layer 12 are formed on the substrate 10 of the mother substrate MB (process PR1 in FIG. 8). Subsequently, as shown in FIG. 9A, the lower electrodes LE1, LE2 and LE3 are formed on the organic insulating layer 12 (process PR2 in FIG. 8).

Subsequently, as shown in FIG. 9B, the rib layer 5 which covers the lower electrodes LE1, LE2 and LE3 is formed in the entire mother substrate MB (process PR3 in FIG. 8). At this time, the pixel aperture AP1, AP2 or AP3 is not provided in the rib layer 5. The rib layer 5 may be formed by chemical vapor deposition (CVD).

After the formation of the rib layer 5, a process for forming the partition 6A is performed (process PR4 in FIG. 8). In process PR4, as shown in FIG. 9C, a first layer L1 which is processed so as to be the bottom layer 63, a second layer L2 which is processed so as to be the stem layer 64, a third layer L3 which is processed so as to be the first top layer 65 and a fourth layer L4 which is processed so as to be the second top layer 66 are formed in order in the entire mother substrate MB. Further, a resist R1 is provided on the fourth layer L4. The resist R1 has been patterned into the shape of the partition 6A. The first layer L1, the second layer L2, the third layer L3 and the fourth layer L4 are formed by, for example, sputtering.

Subsequently, the first layer L1, the second layer L2, the third layer L3 and the fourth layer L4 are patterned using the resist R1 as a mask. For example, the first layer L1 is formed of titanium nitride. The second layer L2 is formed of aluminum. The third layer L3 is formed of titanium. The fourth layer L4 is formed of ITO. In this case, the above patterning may include wet etching for removing the portion of the fourth layer L4 exposed from the resist R1, dry etching for removing the portions of the first, second and third layers L1, L2 and L3 exposed from the resist R1, and wet etching for reducing the width of the second layer L2.

Through process PR4, as shown in FIG. 9D, the partition 6A is formed in the display area DA. After the formation of the partition 6A, the resist R1 is removed (peeled off). In the above wet etching for reducing the width of the second layer L2, the second top layer 66 (fourth layer L4) could be also slightly corroded. When this corrosion occurs, the width of the second top layer 66 becomes less than that of the first top layer 65.

Subsequently, a process for providing the pixel apertures AP1, AP2 and AP3 is performed (process PR5 in FIG. 8). In this process PR5, as shown in FIG. 9E, a resist R2 which covers the partition 6A is formed. Further, dry etching for the rib layer 5 is performed using the resist R2 as a mask. By this process, as shown in FIG. 9F, the pixel apertures AP1, AP2 and AP3 from which the lower electrodes LE1, LE2 and LE3 are exposed are formed in the rib layer 5. After the dry etching described above, the resist R2 is removed (peeled off).

After process PR5, a process for removing the rib layer 5 in the inspection pads TD1 and TD2 shown in FIG. 5 is performed (process PR6 in FIG. 8). In process PR6, a resist which is open in the inspection pads TD1 and TD2 is provided on the rib layer 5, and dry etching is performed for the rib layer 5.

After process PR6, a process for forming the display element DE1 is performed (process PR7 in FIG. 8). To form the display element DE1, first, as shown in FIG. 9G, the stacked film FL1 and the sealing layer SE11 are formed. The stacked film FL1 includes, as shown in FIG. 3, the organic layer OR1 which is in contact with the lower electrode LE1 through the pixel aperture AP1, the upper electrode UE1 which covers the organic layer OR1 and the cap layer CP1 which covers the upper electrode UE1. The organic layer OR1, the upper electrode UE1 and the cap layer CP1 may be formed by, for example, vapor deposition. The sealing layer SE11 may be formed by, for example, CVD.

The stacked film FL1 and the sealing layer SE11 are formed in the entire mother substrate MB including the surrounding area SA and the margin area BA as well as the display area DA of each panel portion PP. The stacked film FL1 is divided into a plurality of portions by the partition 6A having an overhang shape. The sealing layer SE11 continuously covers the portions into which the stacked film FL1 is divided, and the partition 6A.

Subsequently, the stacked film FL1 and the sealing layer SE11 are patterned. In this patterning, as shown in FIG. 9G, a resist R3 is provided on the sealing layer SE11. The resist R3 covers subpixel SP1 and part of the partition 6A around the subpixel.

Subsequently, an etching process using the resist R3 a mask is performed. By this process, as shown in FIG. 9H, the portions of the stacked film FL1 and the sealing layer SE11 exposed from the resist R3 are removed. In other words, of the stacked film FL1 and the sealing layer SE11, the portions which overlap the lower electrode LE1 remain, and the other portions are removed. By this process, the display element DE1 is formed in subpixel SP1. For example, in the surrounding area SA and the margin area BA, the stacked film FL1 and the sealing layer SE11 are removed by this etching process. This etching process may include wet etching and dry etching processes which are performed in order for the sealing layer SE11, the cap layer CP1, the upper electrode UE1 and the organic layer OR1. After these etching processes, the resist R3 is removed (peeled off).

After process PR7, a process for forming the display element DE2 is performed (process PR8 in FIG. 8). The display element DE2 can be formed by a procedure similar to that of the display element DE1. Specifically, when the display element DE2 is formed, the stacked film FL2 and the sealing layer SE12 are formed in the entire mother substrate MB. The stacked film FL2 includes, as shown in FIG. 3, the organic layer OR2 which is in contact with the lower electrode LE2 through the pixel aperture AP2, the upper electrode UE2 which covers the organic layer OR2 and the cap layer CP2 which covers the upper electrode UE2.

The organic layer OR2, the upper electrode UE2 and the cap layer CP2 may be formed by, for example, vapor deposition. The sealing layer SE12 may be formed by, for example, CVD. The stacked film FL2 is divided into a plurality of portions by the partition 6A having an overhang shape. The sealing layer SE12 continuously covers the portions into which the stacked film FL2 is divided, and the partition 6A. By patterning these stacked film FL2 and sealing layer SE2, the display element DE2 is formed in subpixel SP2 as shown in FIG. 9I. For example, in the surrounding area SA and the margin area BA, the stacked film FL2 and the sealing layer SE12 are removed by the etching at the time of this patterning.

After process PR8, a process for forming the display element DE3 is performed (process PR9 in FIG. 8). The display element DE3 can be formed by a procedure similar to the procedures of the display elements DE1 and DE2. Specifically, when the display element DE3 is formed, the stacked film FL3 and the sealing layer SE13 are formed in the entire mother substrate MB. The stacked film FL3 includes, as shown in FIG. 3, the organic layer OR3 which is in contact with the lower electrode LE3 through the pixel aperture AP3, the upper electrode UE3 which covers the organic layer OR3 and the cap layer CP3 which covers the upper electrode UE3.

The organic layer OR3, the upper electrode UE3 and the cap layer CP3 may be formed by, for example, vapor deposition. The sealing layer SE13 may be formed by, for example, CVD. The stacked film FL3 is divided into a plurality of portions by the partition 6A having an overhang shape. The sealing layer SE13 continuously covers the portions into which the stacked film FL3 is divided, and the partition 6A. By patterning these stacked film FL3 and sealing layer SE13, the display element DE3 is formed in subpixel SP3 as shown in FIG. 9J. For example, in the surrounding area SA and the margin area BA, the stacked film FL3 and the sealing layer SE13 are removed by the etching at the time of this patterning.

Here, it is assumed that the display elements DE1, DE2 and DE3 are formed in this order. However, the display elements DE1, DE2 and DE3 may be formed in another order.

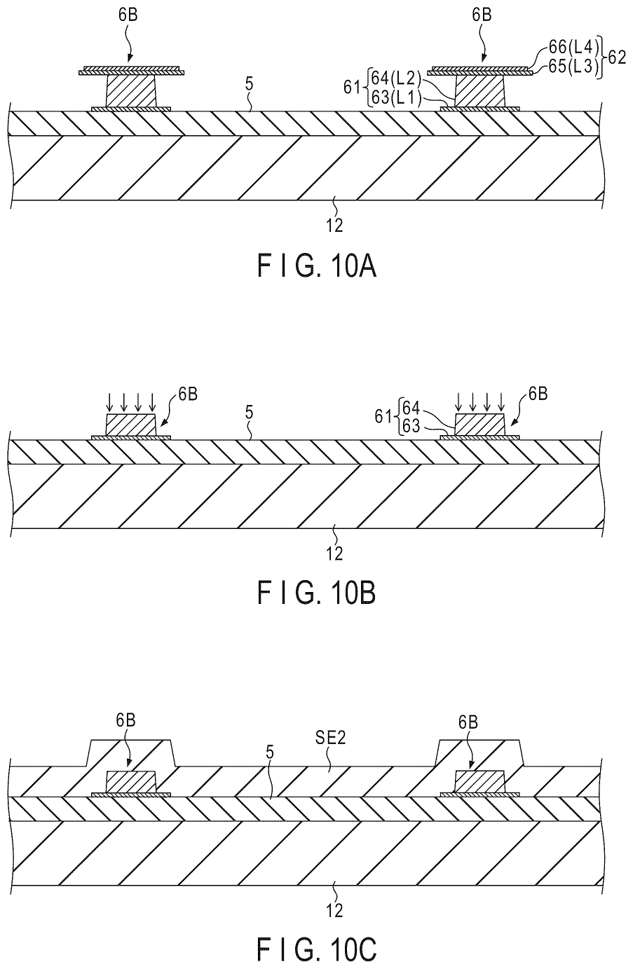

Each of FIG. 10A to FIG. 10C is a schematic cross-sectional view showing the partitions 6B and the surrounding structure in the manufacturing process of the display device DSP. The partitions 6B in the surrounding area SA and the margin area BA are formed together with the partition 6A in process PR4. Immediately after process PR4, as shown in FIG. 10A, each partition 6B has an overhang shape comprising the lower portion 61 and the upper portion 62. The bottom layer 63, stem layer 64, first top layer 65 and second top layer 66 of each of these partitions 6B are formed by processing the first layer L1, second layer L2, third layer L3 and fourth layer L4 described above, respectively.

The stacked films FL1, FL2 and FL3 formed by vapor deposition in processes PR7 to PR9 may have poor adherence to the base. Therefore, the stacked films FL1, FL2 and FL3 and the sealing layers SE11, SE12 and SE13 which cover these stacked films may be removed from the base when the display device DSP is manufactured.

This removal easily occurs in a case where the stacked films FL1, FL2 and FL3 are continuously formed in a wide range. In the display area DA, the stacked films FL1, FL2 and FL3 are divided into pieces by the partition 6A. Thus, the removal described above is prevented.

In this embodiment, at the time point that the stacked films FL1, FL2 and FL3 are formed, a plurality of partitions 6B each of which has the partition apertures 601B, 602B and 603B and has an overhang shape are provided in the surrounding area SA. By this configuration, the stacked films FL1, FL2 and FL3 are divided into pieces by the partitions 6B in the surrounding area SA as well, and the removal described above is prevented.

After the formation of the display elements DE1, DE2 and DE3, each partition 6B finishes its main function. Therefore, in this embodiment, as shown in FIG. 10B, at least the upper portion 62 of each partition 6B is removed (process PR10 in FIG. 8).

For example, process PR10 includes wet etching for removing the second top layer 66 and dry etching for removing the first top layer 65. By this dry etching, part of the stem layer 64 may be eroded. By this process, thickness Tb of the stem layer 64 of each partition 6B (see FIG. 7) becomes less than thickness Ta of the stem layer 64 of the partition 6A (see FIG. 3).

After process PR10, the resin layer RS1 is formed (process PR1l in FIG. 8). The resin layer RS1 may be formed inside the dam structure DS by, for example, an ink-jet method. The dam structure DS functions to dam up the resin layer RS1 before it is cured.

After process PR11, the sealing layer SE2 is formed in the entire mother substrate MB by, for example, CVD (process PR12 in FIG. 8). For example, the partitions 6B provided outside the dam structure DS in the surrounding area SA and the partitions 6B provided in the margin area BA are covered with the sealing layer SE2 as shown in FIG. 10C. When a partition 6B is provided inside the dam structure DS, this partition 6B is covered with the resin layer RS1.

After process PR12, a process for removing the rib layer 5 and sealing layer SE2 covering the terminal portion T is performed (process PR13 in FIG. 8). Further, a process for removing the sealing layer SE2 located around the terminal portion T is performed (process PR14 in FIG. 8).

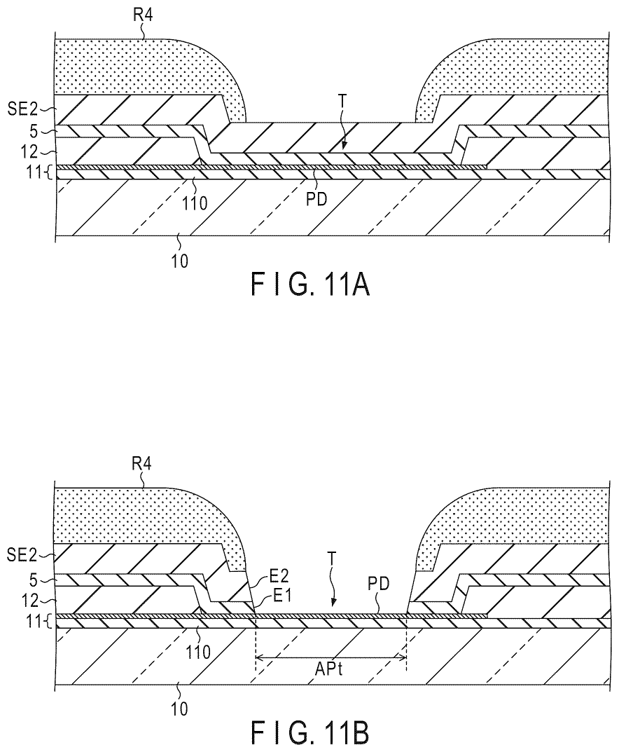

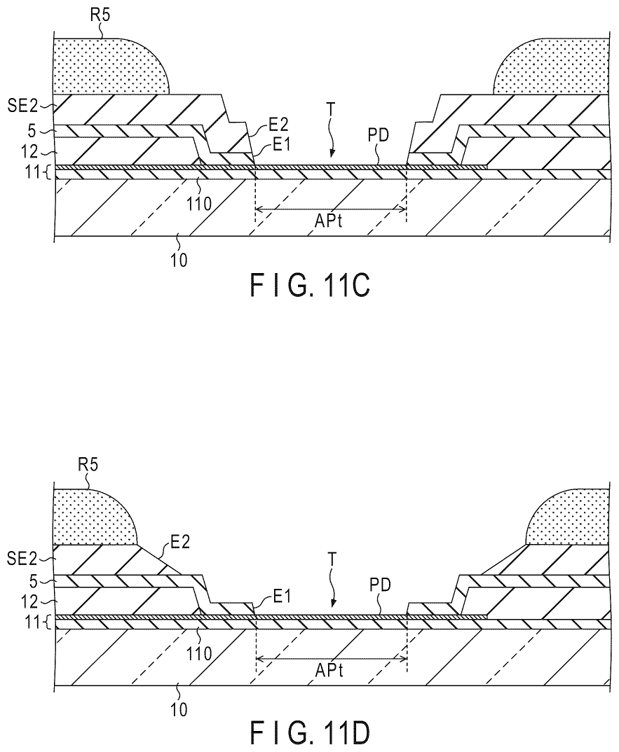

Each of FIG. 11A to FIG. 11D is a schematic cross-sectional view of the terminal portion T for explaining processes PR13 and PR14. As shown in these figures, the terminal portion T comprises a conductive pad PD. The pad PD is provided on an insulating layer 110 formed of, for example, an inorganic insulating material. The pad PD and the insulating layer 110 are included in the circuit layer 11 shown in, for example, FIG. 3. For example, the peripheral portion of the pad PD is covered with the organic insulating layer 12.

At the time of completion of process PR12, as shown in FIG. 11A, the pad PD is covered with the rib layer 5 and the sealing layer SE2. In process PR13, a resist R4 which has a shape which is open on the upper side of the pad PD is provided on the sealing layer SE2. Further, dry etching for the rib layer 5 and the sealing layer SE2 is performed using the resist R4 as a mask. By this process, as shown in FIG. 11B, a terminal aperture APt from which the pad PD is exposed is formed in the rib layer 5 and the sealing layer SE2. After the dry etching described above, the resist R4 is removed (peeled off). For example, in FIG. 11B, the edge portion E1 of the rib layer 5 surrounding the aperture APt and the edge portion E2 of the sealing layer SE2 surrounding the aperture APt are mostly aligned with each other.

In process PR14, as shown in FIG. 11C, a resist R5 which has a shape which is open so as to be larger than the aperture APt above the pad PD is provided on the sealing layer SE2. Further, dry etching for the sealing layer SE2 is performed using the resist R5 as a mask. By this process, as shown in FIG. 11D, the edge portion E2 of the sealing layer SE2 is retracted so as to be away from the aperture APt. Further, the edge portion E2 is formed into a taper shape such that the edge portion E2 inclines gently. This shape of the edge portion E2 allows the prevention of problems of connection of the flexible printed circuit for the terminal portion T etc., compared to a case where the edge portions E1 and E2 form a steep wall surface as shown in FIG. 11C. After the dry etching for the sealing layer SE2, the resist R5 is removed (peeled off).

In processes PR13 and PR14, contact apertures for connecting the touch panel electrodes TP and the lines of the circuit layer 11 may be formed in the rib layer 5 and the sealing layer SE2. These contact apertures may be provided in the area located outside the dam structure DS in the surrounding are SA.

After process PR14, the touch panel electrodes TP are formed on the sealing layer SE2 (process PR15 in FIG. 8). Specifically, first, a conductive layer which is processed so as to be the touch panel electrodes TP is formed in the entire mother substrate MB. Subsequently, a resist having a shape corresponding to the touch panel electrodes TP is provided, and the conductive layer is etched using the resist as a mask. After this etching, the resist is removed (peeled off).

After process PR15, the resin layer RS2 is formed (process PR16 in FIG. 8). The resin layer RS2 may be formed inside the dam structure DS by, for example, an ink-jet method. The dam structure DS functions to dam up the resin layer RS2 before it is cured.

The resin layer RS2 may be formed by a photolithographic process. In this case, first, a photosensitive resin which is processed so as to be the resin layer RS2 is formed in the entire mother substrate MB. Subsequently, the processes of pre-bake, exposure, development and burning are performed for the photosensitive resin. Through these processes, the resin layer RS2 is formed in each panel portion PP.

After process PR16, each panel portion PP is cut out from the mother substrate MB along the cut line CL1 (process PR17 in FIG. 8). Further, the inspection area TA is cut along the cut line CL2 (process PR18 in FIG. 8). In this manner, the display panel PNL is completed.

The embodiment described above can improve the yield of the display device DSP. As described above, since the partitions 6B are provided in the surrounding area SA and the margin area BA, it is possible to prevent the removal of the stacked films FL1, FL2 and FL3 formed in the surrounding area SA and the margin area BA in the manufacturing process of the display device DSP, and the sealing layers SE11, SE12 and SE13 covering the stacked films. If particles generated by this removal are attached to the mother substrate MB, a problem may occur in the display device DSP to be manufactured. Further, the chambers of the manufacturing line need to be cleaned. Thus, the yield of the display device DSP is improved in the configuration of the embodiment by preventing the above problems.

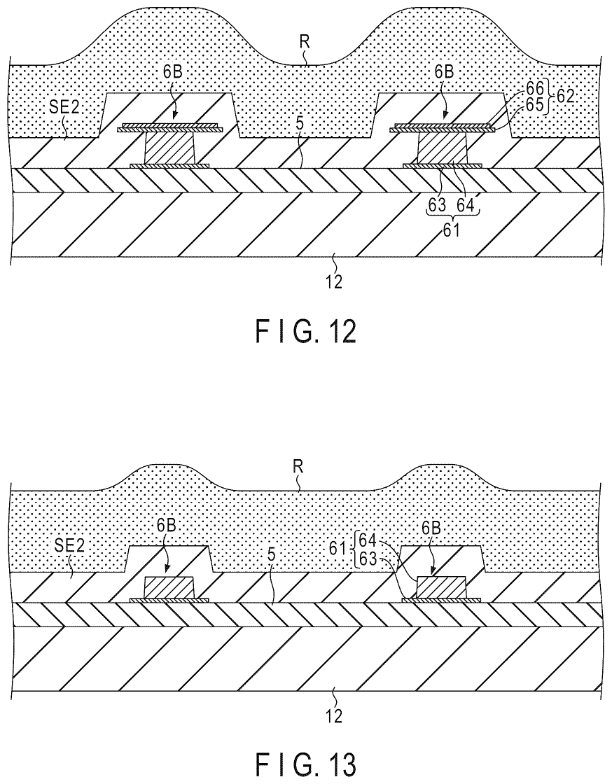

FIG. 12 is a schematic cross-sectional view of partitions 6B according to a comparative example of the embodiment. In this comparative example, this specification assumes a case where process PR10 for removing at least the upper portion of each partition 6B is not performed. In this case, as shown in FIG. 12, each partition 6B comprising a lower portion 61 and an upper portion 62 is covered with a sealing layer SE2 formed in process PR12.

Uneven portions corresponding to the partitions 6B are generated in the sealing layer SE2. Further, uneven portions corresponding to the partitions 6B are generated in a resist R which is formed in the subsequent process. For example, for the resist R, the resist R4 formed in process PR13, the resist PR5 formed in process PR14 and further, the resist formed in process PR15 are considered.

If the unevenness of the resist R is considerable, an air bubble may be included in part of the resist R. In this case, the air bubble may burst in the subsequent reduced-pressure drying process, and the area which should be covered with the resist R under normal conditions could be exposed from the resist R.

Further, as shown in FIG. 5, the inspection pads TD1 and TD2 and the alignment marks MK are provided in the inspection area TA and the margin area BA. There is a possibility that, around these elements, a difference is generated in the application speed of the resist R, thereby inducing the inclusion of an air bubble in the resist R.

FIG. 13 is a schematic cross-sectional view of the partitions 6B according to the embodiment. In this embodiment, each partition 6B does not have at least the upper portion 62. Thus, each partition 6B does not have the overhang shape of the comparative example. Further, as the height is reduced, the unevenness of the resist R is gentle. Thus, the resist R can be also formed satisfactorily, and the phenomenon in which the resist bursts as described above does not easily occur. As a result, the yield of the display device DSP can be improved.

In a case where the resin layer RS2 is formed by a photolithographic process, the photosensitive resin which is the material of the resin layer RS2 also covers the uneven portions generated in the sealing layer SE2 because of the partitions 6B. For this reason, there is a possibility that the photosensitive resin bursts in a manner similar to that of the phenomenon in which the resist bursts as described above. The configuration of the embodiment can also prevent this phenomenon in which the photosensitive resin bursts.

In addition to the effects described above, various desirable effects can be obtained from the embodiment.

### Second Embodiment

A second embodiment is explained. Regarding a display device DSP, a mother substrate MB and the manufacturing method of the display device DSP, configurations similar to those of the first embodiment can be applied to configurations which are not particularly referred to in this embodiment.

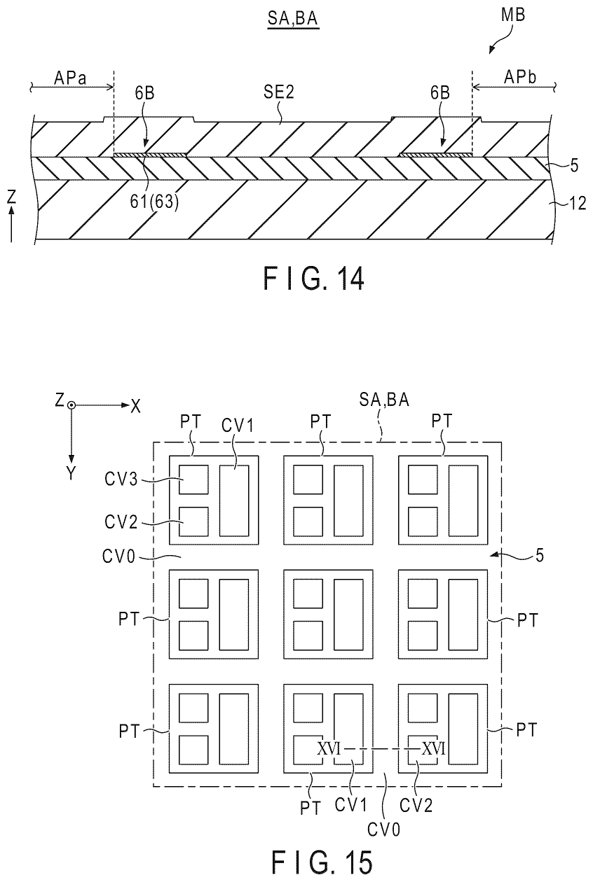

FIG. 14 is a schematic cross-sectional view of the mother substrate MB according to the second embodiment. In this embodiment, in process PR10 shown in FIG. 8, the whole stem layer 64 of each partition 6B is removed, and a bottom layer 63 remains. Thus, after process PR10, each partition 6B includes the bottom layer 63; however, each partition 6B does not includes an upper portion 62 or stem layer 64. The bottom layer 63 of each partition 6B is covered with a sealing layer SE2. From another viewpoint, the bottom layer 63 of each partition 6B is directly in contact with the sealing layer SE2.

In this configuration, the unevenness of the sealing layer SE2 which covers the partitions 6B is further eased. As a result, the phenomenon in which the resist bursts as described above can be further satisfactorily prevented.

It should be noted that the stem layer 64 may not be necessarily removed in all of the partitions 6B provided in the mother substrate MB. For example, the mother substrate MB may include both the structure shown in FIG. 14 and the structure shown in FIG. 7.

In this embodiment and the other embodiments, the term “partition” does not refer to only a wall element which separates an area, and includes an element formed by part of the lower portion 61 and the upper portion 62 like the partitions 6B exemplarily shown in FIG. 14.

### Third Embodiment

A third embodiment is explained. Regarding a display device DSP, a mother substrate MB and the manufacturing method of the display device DSP, configurations similar to those of the first embodiment can be applied to configurations which are not particularly referred to in this embodiment.

In this embodiment, in process PR10 shown in FIG. 8, the lower portion 61 and upper portion 62 of each partition 6B are entirely removed. Thus, after process PR1, the partitions 6B are lost.

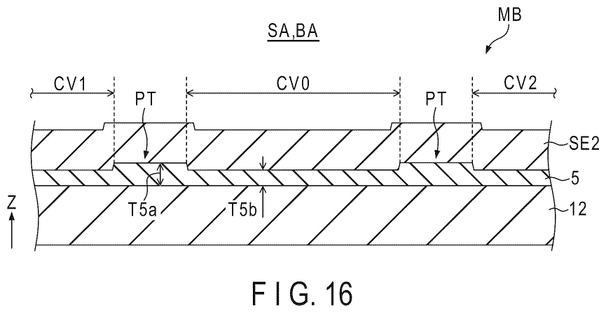

FIG. 15 is a schematic plan view of the surrounding area SA or margin area BA of the mother substrate MB according to the third embodiment. FIG. 16 is the schematic cross-sectional view of the mother substrate MB along the XVI-XVI line of FIG. 15.

In the portions shown in FIG. 15 and FIG. 16, the partitions 6B are not provided. It should be noted that, however, a rib layer 5 has a plurality of protrusions PT having a planar shape similar to that of the partitions 6B shown in FIG. 6.

As shown in FIG. 15, the rib layer 5 has a recess CV0 between adjacent protrusions PT, and recesses (first to third recesses) CV1, CV2 and CV3 surrounded by each protrusion PT. The recesses CV1, CV2 and CV3 have planar shapes similar to those of the partition apertures 601A, 602A and 603A shown in FIG. 2, respectively. The relative positional relationship of the recesses CV1, CV2 and CV3 is similar to that of the partition apertures 601A, 602A and 603A.

As shown in FIG. 16, each protrusion PT has thickness T5a. The recesses CV0, CV1, CV2 and CV3 have thickness T5b which is less than thickness T5a (T5b<T5a). In the example of FIG. 16, the base of the rib layer 5 (the upper surface of an organic insulating layer 12) is flat. In other words, the protrusions PT and the recesses CV0, CV1, CV2 and CV3 correspond to the unevenness which is generated on the upper surface of the rib layer 5 because of the difference in the thickness of the rib layer 5.

The recesses CV0, CV1, CV2 and CV3 are formed in process PR10. Thus, the upper surface of the rib layer 5 is eroded in etching for removing the partitions 6B, particularly dry etching for removing a stem layer 64 and a bottom layer 63. This erosion is noticeable in the portion exposed from the bottom layer 63. Therefore, after process PR10, the protrusions PT corresponding to the planar shapes of the partitions 6B and the surrounding recesses CV0, CV1, CV2 and CV3 are generated in the rib layer 5.

In the configuration of this embodiment, the unevenness of a sealing layer SE2 in the surrounding area SA and the margin area BA is further eased. As a result, the phenomenon in which a resist bursts as described above can be further satisfactorily prevented.

It should be noted that all of the partitions 6B provided in the mother substrate MB may not be necessarily removed. For example, the mother substrate MB may include both the structure shown in FIG. 16 and the structure shown in FIG. 7. The mother substrate MB may include the structure shown in FIG. 14.

In the configuration of the first or second embodiment, the recesses CV0, CV1, CV2 and CV3 may be formed around the bottom layers 63 of the partitions 6B. In this case, the bottom layers 63 of the partitions 6B are located on the protrusions PT.

### Fourth Embodiment

A fourth embodiment is explained. Regarding a display device DSP, a mother substrate MB and the manufacturing method of the display device DSP, configurations similar to those of the each of the embodiments described above can be applied to configurations which are not particularly referred to in this embodiment.

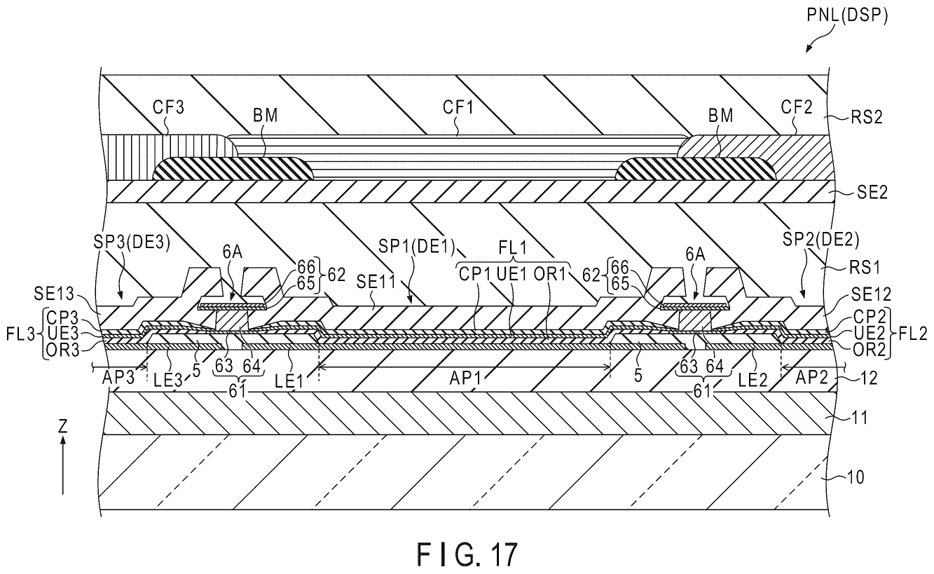

FIG. 17 is a schematic cross-sectional view of a display panel PNL (display device DSP) according to the fourth embodiment. In this embodiment, a light-shielding layer BM is provided above a partition 6A. Further, a color filter CF1 for a first color is provided above a display element DE1. A color filter CF2 for a second color is provided above a display element DE2. A color filter CF3 for a third color is provided above a display element DE3. The first color, the second color and the third color are, for example, blue, green and red. However, the colors are not limited to this example.

The light-shielding layer BM and the color filters CF1, CF2 and CF3 are located on a sealing layer SE2. For example, the planar shape of the light-shielding layer BM in a display area DA is similar to that of the partition 6A or that of a rib layer 5.

In the example of FIG. 17, the light-shielding layer BM is covered with the color filters CF1, CF2 and CF3. The color filters CF1, CF2 and CF3 are covered with a resin layer RS2. It should be noted that the layout position of the color filter CF1, CF2 or CF3 or the light-shielding layer BM is not limited to this example.

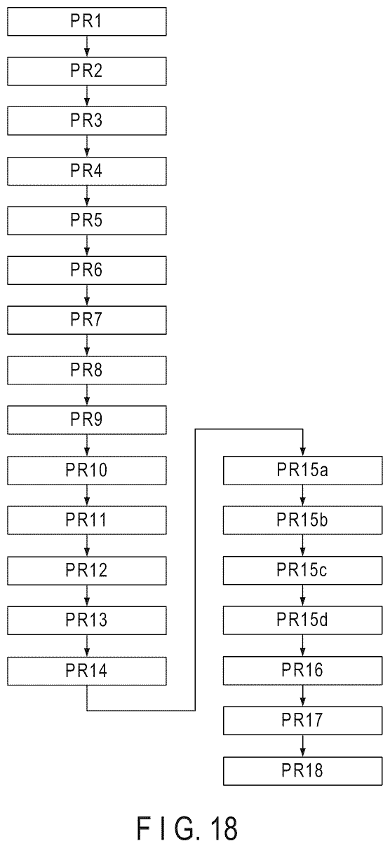

FIG. 18 is a flowchart showing an example of the manufacturing method of the display device DSP according to the embodiment. In this embodiment, instead of process PR15 of the flowchart of FIG. 8 (the formation of the touch panel electrodes TP), processes PR15a, PR15b, PR15c and PR15d are performed.

In process PR15a, the light-shielding layer BM is formed on the sealing layer SE2. In process PR15b, the color filter CF2 is formed on the sealing layer SE2. In process PR15c, the color filter CF3 is formed on the sealing layer SE2. In process PR15d, the color filter CF1 is formed on the sealing layer SE2. It should be noted that the formation order of the color filters CF1, CF2 and CF3 is not limited to this example.

For example, the light-shielding layer BM may be formed by a photolithographic process. In this case, first, a photosensitive resin which is processed so as to be the light-shielding layer BM is formed in the entire mother substrate MB. Subsequently, the processes of pre-bake, exposure, development and burning are performed for the photosensitive resin. Through these processes, the light-shielding layer BM is formed in each panel portion PP. The color filters CF1, CF2 and CF3 can be formed by a photolithographic process similar to that for the photosensitive resin.

The photosensitive resins to be processed into the light-shielding layer BM and the color filters CF1, CF2 and CF3 also cover the unevenness generated in the sealing layer SE2 because of partitions 6B. Therefore, when the unevenness of the sealing layer SE2 is considerable in a surrounding area SA and a margin area BA, in a manner similar to that of the phenomenon in which the resist bursts as described above, the photosensitive resins may burst. In this regard, when the surrounding area SA and the margin area BA comprise the configurations shown in the first to third embodiments (see FIG. 7, FIG. 14 and FIG. 16), this burst of the photosensitive resins can be also prevented.

It should be noted that the display device DSP may comprise touch panel electrodes TP in addition to the light-shielding layer BM and the color filters CF1, CF2 and CF3. In this case, process PR15 for forming the touch panel electrodes TP may be performed before processes PR15a, PR15b, PR15c and PR15d for forming the light-shielding layer BM and the color filters CF1, CF2 and CF3. As another example, process PR15 may be performed after processes PR15a, PR15b, PR15c and PR15d.

### Fifth Embodiment

A fifth embodiment is explained. Regarding a display device DSP, a mother substrate MB and the manufacturing method of the display device DSP, configurations similar to those of the each of the embodiments described above can be applied to configurations which are not particularly referred to in this embodiment.

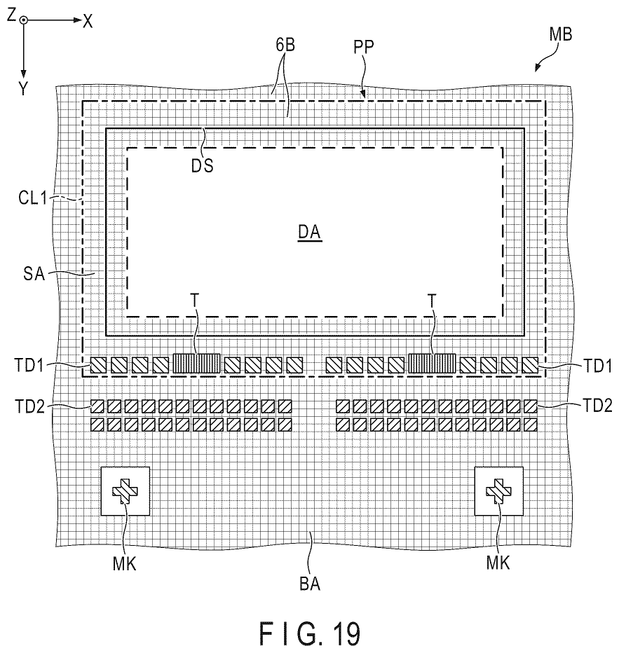

FIG. 19 is a schematic plan view of the mother substrate MB according to the embodiment. In this embodiment, each of a display area DA and a dam portion DS is a rectangle which is long in an X-direction. A panel portion PP comprises two terminal portions T. Even if the panel portion PP has this configuration, by applying the configurations disclosed in the first to fourth embodiments, effects similar to those of each embodiment can be obtained.

It should be noted that various other forms may be applied to the configuration of the panel portion PP. For example, the display area DA of each panel portion PP may be a rectangle which is long in a Y-direction, or may be a square. The display area DA may have a shape including a plurality of linear portions and curved portions.

All of the display devices, mother substrates and manufacturing methods that can be implemented by a person of ordinary skill in the art through arbitrary design changes to the display device, mother substrate and manufacturing method disclosed in each of the embodiments described above come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

Examples of display devices, mother substrates and manufacturing methods which can be recognized by the above embodiments are described below.

(1) A mother substrate for a display device, the mother substrate comprising:
a plurality of panel portions each of which includes a display area and a surrounding area around the display area;
a margin area around the panel portions;
a display element in the display area;
a rib layer which is in the panel portions and the margin area and has a pixel aperture overlapping the display element;
a first partition which is in the display area and surrounds the pixel aperture; and
a second partition which is in at least one of the surrounding area and the margin area, wherein
the first partition includes a lower portion above the rib layer and an upper portion having an end portion protruding from a side surface of the lower portion, and
the second partition includes at least part of the lower portion and does not include the upper portion.

(2) The mother substrate of the above (1), wherein
the lower portion of the first partition includes a bottom layer above the rib layer, and a stem layer above the bottom layer.

(3) The mother substrate of the above (2), wherein
the second partition includes the bottom layer and the stem layer, and
the stem layer of the second partition is thinner than the stem layer of the first partition.

(4) The mother substrate of the above (2), wherein
the lower portion of the second partition includes the bottom layer and does not include the stem layer.

(5) A mother substrate for a display device, the mother substrate comprising:
a plurality of panel portions each of which includes a display area and a surrounding area around the display area;
a margin area located around the panel portions;
a display element provided in the display area;
a rib layer which is in the panel portions and the margin area and has a pixel aperture overlapping the display element; and
a first partition which is in the display area and has a partition aperture overlapping the pixel aperture, wherein
in at least one of the surrounding area and the margin area, the rib layer has:
   a recess having a planar shape similar to the partition aperture; and
   a protrusion surrounding the recess.

(6) The mother substrate of the above (5), wherein
a thickness of the rib layer in the recess is less than a thickness of the rib layer in the protrusion.

(7) The mother substrate of the above (5), wherein
the display element includes first to third display elements which emit light exhibiting first to third colors, respectively, which are different from each other,
the pixel aperture includes first to third pixel apertures which overlap the first to third display elements, respectively,
the partition aperture includes first to third partition apertures which overlap the first to third pixel apertures, respectively, and
the recess includes first to third recesses which have planar shapes similar to the first to third partition apertures, respectively.

(8) A display device comprising:
a display area;
a surrounding area around the display area;
a display element in the display area;
a rib layer having a pixel aperture overlapping the display element;
a first partition which is in the display area and surrounds the pixel aperture; and
a second partition in the surrounding area, wherein
the first partition includes a lower portion above the rib layer, and an upper portion having an end portion protruding from a side surface of the lower portion, and
the second partition includes at least part of the lower portion and does not include the upper portion.

(9) The display device of the above (8), wherein
the lower portion of the first partition includes a bottom layer above the rib layer, and a stem layer above the bottom layer.

(10) The display device of the above (9), wherein
the second partition includes the bottom layer and the stem layer, and
the stem layer of the second partition is thinner than the stem layer of the first partition.

(11) The display device of the above (9), wherein
the lower portion of the second partition includes the bottom layer and does not include the stem layer.

(12) A display device comprising:
a display area;
a surrounding area around the display area;
a display element in the display area;
a rib layer having a pixel aperture overlapping the display element; and
a first partition which is in the display area and has a partition aperture overlapping the pixel aperture, wherein
in the surrounding area, the rib layer has:
   a recess having a planar shape similar to the partition aperture; and
   a protrusion surrounding the recess.

(13) The display device of the above (12), wherein
a thickness of the rib layer in the recess is less than a thickness of the rib layer in the protrusion.

(14) The display device of the above (12), wherein
the display element includes first to third display elements which emit light exhibiting first to third colors, respectively, which are different from each other,
the pixel aperture includes first to third pixel apertures which overlap the first to third display elements, respectively,
the partition aperture includes first to third partition apertures which overlap the first to third pixel apertures, respectively, and
the recess includes first to third recesses which have planar shapes similar to the first to third partition apertures, respectively.

(15) A manufacturing method of a display device, the method including:
preparing a substrate including:
   panel portions each of which includes a display area and a surrounding area around the display area; and
   a margin area around the panel portions;
forming a rib layer in the panel portions and the margin area;
forming, in the display area, a first partition including a lower portion and an upper portion having an end portion protruding from a side surface of the lower portion;
forming, in at least one of the margin area and the surrounding area, a second partition including the lower portion and the upper portion;
forming a display element in an area surrounded by the first partition in the display area; and
removing at least the upper portion from the second partition.

(16) The manufacturing method of the above (15), wherein
the lower portion of each of the first partition and the second partition before the removal process includes a bottom layer provided above the rib layer, and a stem layer provided on the bottom layer, and
in the removal process, a thickness of the stem layer of the second partition is reduced.

(17) The manufacturing method of the above (15), wherein
the lower portion of each of the first partition and the second partition before the removal process includes a bottom layer provided above the rib layer, and a stem layer provided on the bottom layer, and
in the removal process, the stem layer of the second partition is removed, and further, the bottom layer of the second partition remains.

(18)
The manufacturing method of the above (17), wherein
the lower portion of the second partition is entirely removed in the removal process.

(19) The manufacturing method of the above (15), further including:
forming a sealing layer by an inorganic insulating material in the panel portions and the margin area after the removal process; and
forming a touch panel electrode above the sealing layer.

(20) The manufacturing method of the above (15), further including:
forming a sealing layer by an inorganic insulating material in the panel portions and the margin area after the removal process; and
forming a color filter above the sealing layer.

What is claimed is:

1. A mother substrate for a display device, the mother substrate comprising:
a plurality of panel portions each of which includes a display area and a surrounding area around the display area;
a margin area around the panel portions;
a display element in the display area;
a rib layer which is in the panel portions and the margin area and has a pixel aperture overlapping the display element;
a first partition which is in the display area and surrounds the pixel aperture; and
a second partition which is in at least one of the surrounding area and the margin area, wherein
the first partition includes a lower portion above the rib layer and an upper portion having an end portion protruding from a side surface of the lower portion, and
the second partition includes at least part of the lower portion and does not include the upper portion.

2. The mother substrate of claim 1, further comprising a second sealing layer covering the display area, the surrounding area and the margin area, wherein
the second partition is covered with the second sealing layer.

3. The mother substrate of claim 1, wherein
the lower portion of the first partition includes a bottom layer above the rib layer, and a stem layer above the bottom layer.

4. The mother substrate of claim 3, wherein
the second partition includes the bottom layer and the stem layer, and
the stem layer of the second partition is thinner than the stem layer of the first partition.

5. The mother substrate of claim 3, wherein
the second partition includes the bottom layer and the stem layer,
the bottom layer of the second partition and the bottom layer of the first partition are formed of a same material, and
the stem layer of the second partition and the stem layer of the first partition are formed of a same material.

6. The mother substrate of claim 3, further comprising a second sealing layer covering the display area, the surrounding area and the margin area, wherein
the second partition includes the bottom layer and the stem layer,
the second partition is covered with the second sealing layer, and
the bottom layer of the second partition and the stem layer of the second partition are directly in contact with the second sealing layer.

7. The mother substrate of claim 3, wherein
the second partition includes the bottom layer and does not include the stem layer.

8. The mother substrate of claim 7, wherein
the bottom layer of the second partition and the bottom layer of the first partition are formed of a same material.

9. The mother substrate of claim 8, further comprising a second sealing layer covering the display area, the surrounding area and the margin area, wherein
the bottom layer of the second partition is covered with the second sealing layer.

10. The mother substrate of claim 9, wherein
the bottom layer of the second partition is directly in contact with the second sealing layer.

11. A display device comprising:
a display area;
a surrounding area around the display area;
a display element in the display area;
a rib layer having a pixel aperture overlapping the display element;
a first partition which is in the display area and surrounds the pixel aperture; and
a second partition in the surrounding area, wherein
the first partition includes a lower portion above the rib layer, and an upper portion having an end portion protruding from a side surface of the lower portion, and
the second partition includes at least part of the lower portion and does not include the upper portion.

12. The display device of claim 11, further comprising a second sealing layer which covering the display area and the surrounding area, wherein
the second partition is covered with the second sealing layer.

13. The display device of claim 11, wherein
the lower portion of the first partition includes a bottom layer above the rib layer, and a stem layer above the bottom layer.

14. The display device of claim 13, wherein
the second partition includes the bottom layer and the stem layer, and
the stem layer of the second partition is thinner than the stem layer of the first partition.

15. The display device of claim 13, wherein
the second partition includes the bottom layer and the stem layer,
the bottom layer of the second partition and the bottom layer of the first partition are formed of a same material, and
the stem layer of the second partition and the stem layer of the first partition are formed of a same material.

16. The display device of claim 13, further comprising a second sealing layer covering the display area and the surrounding area, wherein
the second partition includes the bottom layer and the stem layer,
the second partition is covered with the second sealing layer, and
the bottom layer of the second partition and the stem layer of the second partition are directly in contact with the second sealing layer.

17. The display device of claim 13, wherein
the second partition includes the bottom layer and does not include the stem layer.

18. The display device of claim 17, wherein
the bottom layer of the second partition and the bottom layer of the first partition are formed of a same material.

19. The display device of claim 18, further comprising a second sealing layer covering the display area and the surrounding area, and
the bottom layer of the second partition is covered with the second sealing layer.

20. The display device of claim 19, wherein
the bottom layer of the second partition is directly in contact with the second sealing layer.
